(19) United States
(12) Patent Application Publication
(10) Pub. No.: US 2003/0039893 A1
(43) Pub. Date: Feb. 27, 2003

(54) Exposed phase edge mask method for generating periodic structures with subwavelength feature

(76) Inventors: Jeff Farnsworth, Los Gatos, CA (US); Wen Hao Cheng, Fremont, CA (US); Brian Irvine, Mountain View, CA (US); Chien Chiang, Fremont, CA (US); Alice Wang, Milpitas, CA (US); Gina Wu, Santa Clara, CA (US)

Correspondence Address: Chun M. Ng, BLAKELY, SOKOLOFF, TAYLOR & ZAFMAN LLP, Seventh Floor, 12400 Wilshire Boulevard, Los Angeles, CA, 90025-1026, US

(21) Appl. No.: 09/935,563

(22) Filed: Aug. 22, 2001

(51) Int. Cl. G03F 9/00; G03C 5/00; G03G 16/00

(52) U.S. Cl. 430/5; 430/311; 257/6

(57) ABSTRACT

A method for forming small repeating structures, such as contact holes, is disclosed. The method comprises using a phase shift mask to perform a first exposure of a photoresist layer formed atop of a substrate. The phase shift mask includes etched regions and unetched regions. Next, the position of the phase shift mask is adjusted relative to the photoresist layer. A second exposure through the adjusted phase shift mask is performed on the photoresist layer. The photoresist is developed and is used as a mask for etching the substrate. After etch, the photoresist is stripped and cleaned. The resulted small sub-wavelength pattern is formed from the disclosed technique.

### TECHNICAL FIELD OF THE INVENTION

The present invention relates to the use of phase shift mask in photolithography to generate repeating structures having sub-wavelength dimension.

### BACKGROUND OF THE INVENTION

As technology advances, semiconductor manufacturers must fabricate ever smaller and denser integrated circuits. One of the important steps in the manufacture of integrated circuits is the photolithography process. Photolithography involves the projection of a patterned image onto a layer of photoresist on a semiconductor wafer using an imaging tool and a photomask having a desired pattern formed thereon. After exposure, the photoresist-coated wafer is developed using a developing solution so as to reproduce the imaged pattern.

Depending upon the type of photoresist, a positive or a negative image of the pattern of the photomask is developed in the photoresist layer. For example, if a negative photoresist is used, then the projected exposure radiation passing through the photomask will cause the exposed areas of the photoresist to undergo polymerization. Upon subsequent development, unexposed portions of the negative photoresist will wash off with the developer, leaving a pattern of photoresist material constituting a reverse or negative image of the mask pattern. The remaining photoresist material will serve as a mask in subsequent processing steps, such as etching.

To produce sub-wavelength features, i.e., features smaller than the wavelength of the exposure radiation, manufacturers employ a photolithographic technique known as a phase shift mask technique. The phase shift mask technique uses a mask having a first region that allows transmission of radiation therethrough and an adjacent region that shifts the phase of the radiation traveling therethrough by approximately 180 degrees relative to that of the first region. This 180-degree phase difference causes destructive interference of radiation from the first region and the adjacent region along their interface to thereby enhance contrast of the projected image.

As noted above, the need for higher density integrated circuits has been consistently increased. One example is in the context of memory arrays. Memory arrays are composed of by large two-dimensional repeating memory cells. Each memory cell has a “contact hole” for the metal interconnect between transistors. As the density of the memory arrays increases, the size and pitch of the contact hole must decrease accordingly. The demands of the memory array require that the contact holes be made to have an extremely small dimension. The present invention provides a method for using a phase shift mask to pattern periodic sub-wavelength structures, such as the contact holes required in memory arrays.

### BRIEF DESCRIPTION OF THE FIGURES

The invention is best understood by reference to the Figures wherein references indicate function, structure, and/or element.

FIG. 1 is a schematic diagram of an imaging system using a phase shift mask.

FIG. 2 is a schematic illustration of a phase shift mask formed in accordance with the present invention.

FIG. 3 is a cross-sectional view taken of the last row of the phase shift mask of FIG. 2.

FIG. 4 illustrates a pattern formed on a photoresist using the phase shift mask of FIG. 2 after a first exposure.

FIG. 5 illustrates the pattern formed on the photoresist after a second exposure using the phase shift mask of FIG. 2 after the phase shift mask has been offset.

FIG. 6 shows the pattern of contact holes formed using the method of the present invention.

FIG. 7 shows an alternative embodiment of a phase shift mask formed in accordance with the present invention.

FIG. 8 shows the phase shift mask of FIG. 7 rotated 90 degrees.

FIG. 9 shows the pattern formed on a photoresist layer after double exposure through the phase shift masks of FIGS. 7 and 8.

FIG. 10 is a flow diagram illustrating the method according to the present invention.

### DETAILED DESCRIPTION OF THE PREFERRED EMBODIMENTS

To summarize, in accordance with one embodiment of the present invention, a phase shift mask is formed with a checkerboard pattern. The checkerboard pattern includes alternating regions that have been etched to provide a 180-degree phase shift in transmitted exposure radiation. The checkerboard pattern is then exposed a first time to pattern a photoresist layer that mirrors the checkerboard pattern. A second exposure is performed after the checkerboard phase shift mask has been shifted with a predetermined offset in the x- and y-axes.

In the following description of the preferred embodiments, specific details are provided for thorough understanding of embodiments of the invention. One who is skilled in the relevant art will recognize, that the invention can be practiced without one or more of the specific details, or with other methods, components, materials, etc. In other instances, well-known structures, materials, operations are not shown or described in detail to avoid obscuring aspects of the invention.

Reference throughout this specification to “one embodiment”, “an embodiment”, or “preferred embodiment” means that a particular feature, structure, or characteristic described in connection with the embodiment is included in at least one embodiment of the present invention. Thus, the appearance of the phrase “in one embodiment”, “in an embodiment”, or “in a preferred embodiment” in various places throughout the specification are not necessarily all referring to the same embodiment. Furthermore, the particular features, structures, or characteristic may be combined in any suitable manner in one or more embodiments.

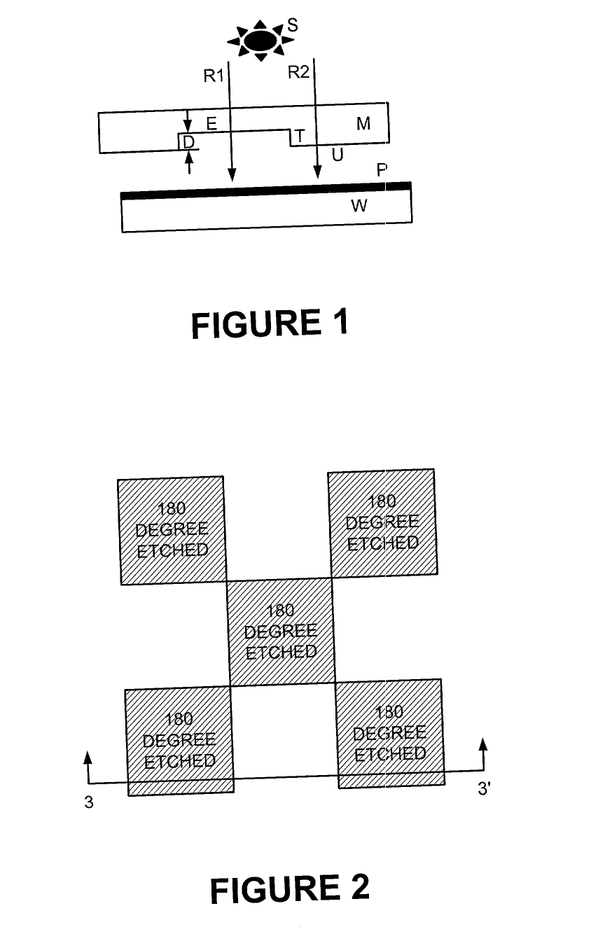

FIG. 1 is a schematic view of an imaging tool used for patterning a photoresist layer on a semiconductor wafer. A phase shift mask M is used in the imaging tool to pattern projected radiation onto a semiconductor wafer. The projected radiation comes from a source S, such as a stepper, to expose photoresist layer P on a semiconductor wafer W. Radiation from source S is indicated by the arrows R1 and R2. A stepper can be characterized by its numerical aperture (NA) and its average wavelength of projected radiation. A deep ultraviolet (DUV) stepper typically has a NA of 0.6 at an average wavelength of 248 nanometers.

Mask M is transmissive to radiation projected from source S and is a chrome-less phase shift mask for device patterning. In other words, mask M does not contain material reflecting or absorbing radiation from source in the device patterning area. Mask M patterns circuit geometry on semiconductor wafer W using radiation from source S with destructive interference effects, in which the optical technique of exposed phase edge is applied.

The substrate of mask M is quartz, but with etched regions E. Etched regions E are etched to a predetermined depth, which is indicated by the bracketed line D. A transition region T is defined as the area where unmodified areas of mask M transitions to the etched regions E. Transition region T borders the circumference of etched region E. Typically, the transition region T is formed as a vertical transition as shown in FIG. 1.

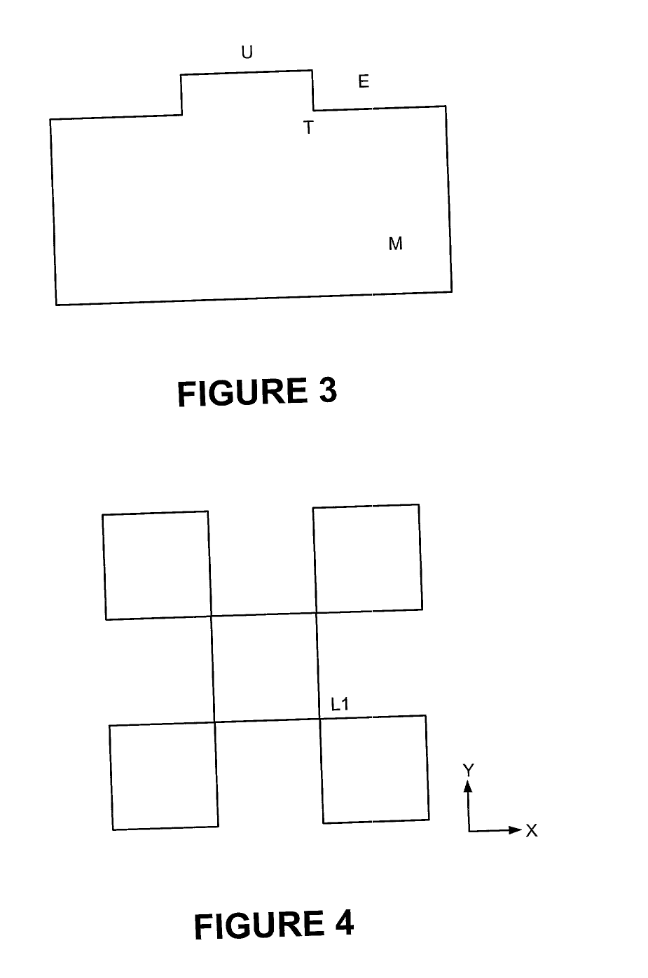

FIG. 2 is an enlarged top view of the mask M and FIG. 3 is a cross sectional view of the last row of mask M taken along line 3-3′. In a phase shift mask, interference effects are used to form feature L1 in the photoresist layer P, as illustrated in FIG. 4. A specific predetermined etching depth is chosen so that radiation passing through the etched region E compared to the unetched mask M is phase shifted 180 degrees. The required predetermined depth D of etched region E can be calculated from the following equation:

D=λ/[2(n−1)],

where is the wavelength of radiation from source S and n is the refractive index of the mask M. For a mask M made of quartz, the value of n at exposure wavelength of 248-nanometer is 1.508.

Interference effects occur as a result of transition region T. Radiation R1 passing through unetched mask M near the transition region T interferes with radiation R2 passing through etched region E (being 180 degrees out of phase to each other), causing destructive interference. Other areas of photoresist layer P on the semiconductor wafer W where destructive interference does not occur is exposed by radiation from source S.

For a wafer W with negative photoresist P, only those areas that underneath transition region T are not exposed to radiation and, during the development process, photoresist underneath transition region T is removed.

With the foregoing principles in mind, a phase shift mask designed in accordance with the present invention is shown in FIG. 3. The phase shift mask M has a checkerboard design and, in this embodiment, has a two dimensional array of alternating etched and unetched regions. A cross-sectional view of the phase shift mask is shown in FIG. 3. Preferably, the phase shift mask is formed of quartz or other type of material that is translucent to the radiation from the imaging tool.

The phase shift mask M has etched regions E with depth D relative to the surface of the phase shift mask M. Un-etched regions U are interspersed in an alternating fashion with etched regions E to form a checkerboard pattern of phase shift mask M. As will be seen below, the dimension and shape of the etched regions E and un-etched regions U may be varied depending upon the desired spacing and location of the contact holes to be formed.

The depth D is determined by the amount of etching, of the quartz material of phase shift mask M necessary in order to implement a 180 degree phase shift between radiation traveling through unetched region U and etched region E. Specifically, as noted above, for a wavelength of 248 nanometers, using the formula given above, the depth D is 243.71 nanometer. If the exposing ultraviolet radiation from source S has a wavelength of 193 nanometers, then the depth D should be 171.7 nanometer, where the index of refraction at an exposure wavelength of 193 nanometer is 1.563.

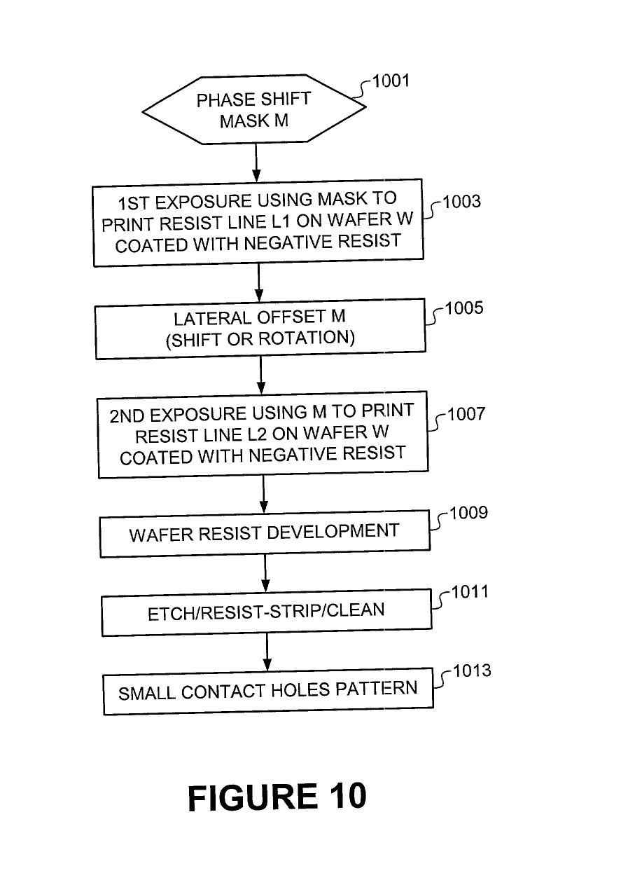

Phase shift mask M can be used to form extremely small features in a photoresist layer using the method of the present invention. The overall method of the present invention is described below and shown in the flow diagram of FIG. 10. Specifically, at steps 1001 and 1003, the phase shift mask M is used to expose the negative photoresist. Because the phase shift mask M is translucent to the exposing radiation, the entire layer of photoresist is exposed to the radiation.

With the use of negative photoresist, radiation exposure causes the negative photoresist to polymerize and harden. However, because of the destructive interference at the transition regions between etched regions E and un-etched regions U, using the checkerboard pattern of FIG. 2, resist lines L1 as shown in FIG. 4 are not exposed to the radiation. As these lines are substantially free from exposure to radiation, the “dark” lines L1 do not experience the polymerizing effect.

Furthermore, by controlling various process parameters, such as the type of negative photoresist used, the wavelength of the exposing radiation, the exposure dosage of the exposing radiation, and other factors such as the illumination's focus offset, the width of the resist lines: LW, as designated in FIG. 4, can be controlled. Typically, the width LW is on the order of 0.1 microns for typical process parameters.

Next, at step 1005, the phase shift mask M is offset or rotated (rotation is used for an alternative embodiment of the present invention disclosed below) such that the transition areas between etched regions E and un-etched regions U overlay different areas on the photoresist layer. A generic term also used here is “lateral-shift” of the phase shift mask, in which the phase shift mask M is offset or rotated in the second exposure. In one embodiment, the phase shift mask M is offset from the first exposure step by one half of the dimension of the square etched region E. This offset is performed in both the x and y directions as shown in FIG. 4.

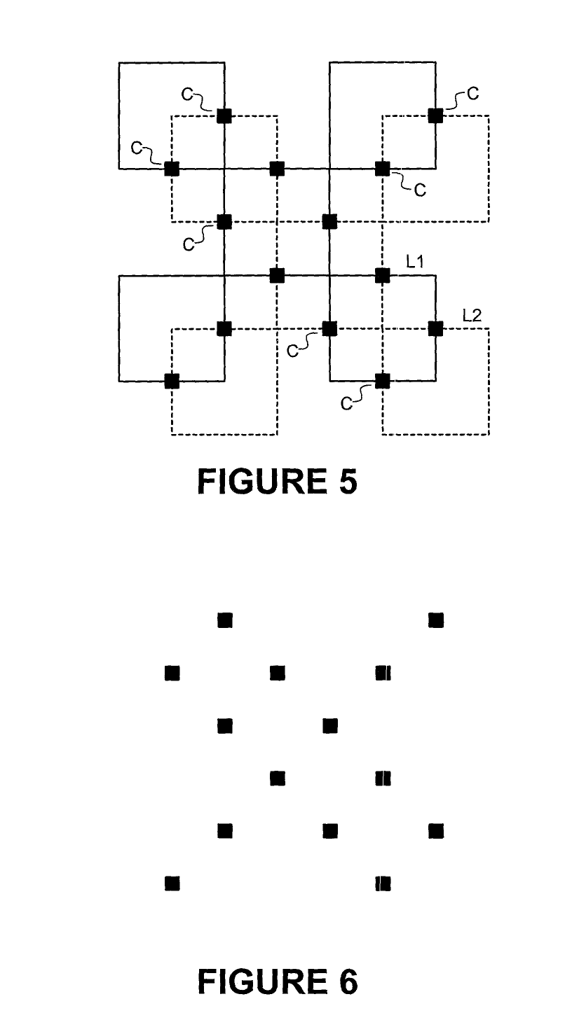

After this offset has been made, at step 1007, the photoresist layer is exposed for a second time using the phase shift mask M with a lateral shift. This second exposure also generates resist lines L2 that are not exposed to the radiation due to destructive interference at the transition areas between the etched regions E and un-etched regions U. However, as seen in FIG. 5, lines that were previously left unexposed in the first exposure are now exposed in the second exposure due to the offset. Note that in FIG. 5, the “dark” lines L2 formed during the second exposure are shown as dashed lines so to distinguish between lines formed by the first exposure. Note that the actual lines L2 formed on the photoresist layer from the second exposure have the same dimension as that from the first exposure L1.

After the second exposure, intersection points C between the lines formed from the first exposure and the second exposure are still not exposed to any radiation that would polymerize the negative photoresist. For the examples shown in FIGS. 4 and 5, the resulting points C that are not exposed to any radiation are shown as a repeating pattern. In nominal conditions, the points C are square shaped corresponding to the intersection of the interference lines from the first and second exposure steps. In one embodiment, the points C are used to form contact holes, and throughout the remainder of this disclosure, points C will be referred to as contact holes C.

Next, at step 1009, the negative photoresist is developed. Because the contact holes C have not been exposed to radiation, these areas of photoresist have not been polymerized and, during the development process, the photoresist in these locations is removed. As seen in FIG. 6, after photo-resist development, what remains is a substantially intact photoresist layer that has contact holes C formed in a repetitive pattern and having a dimension that is substantially less than what was achievable in the prior art. To complete formation of the contact holes, using the photoresist layer as a mask, at step 1011, a conventional etching process is used to etch the underlying silicon substrate layer upon which the photoresist covers on the wafer. When the etch process for the contact holes formation is complete, photoresist is removed and the wafer is cleaned for next silicon process steps. The contact holes are then complete at step 1013.

The example described above with respect to FIGS. 2-6 is one embodiment of the present invention. Various patterns of the phase shift mask M may be used and various lateral shift schemes may be used to generate periodic contact holes C patterning. For example, the dimensions of the etched regions E and the unetched regions U may be varied depending upon the spacing required for the contact holes C from the circuitry design. Additionally, the regions E and U need not be square, but may be rectangular, triangular, or any other shape specifically designed for patterning. Other modifications to the dimension and pattern used to form the phase shift mask M with the method described in the present invention may also be readily apparent to those of ordinary skill in the art given this disclosure herein.

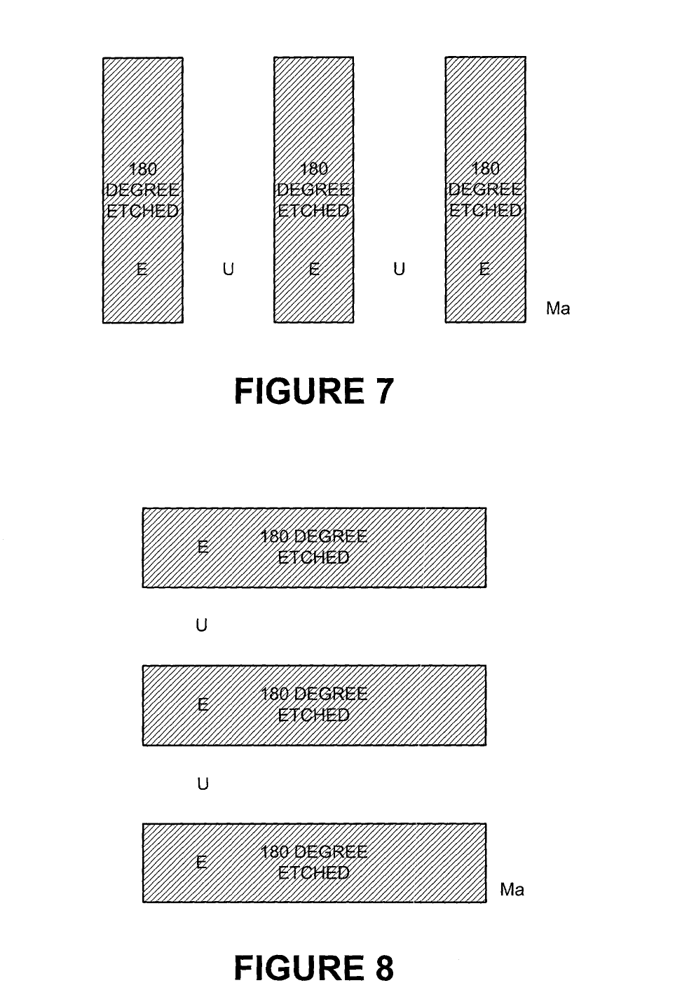

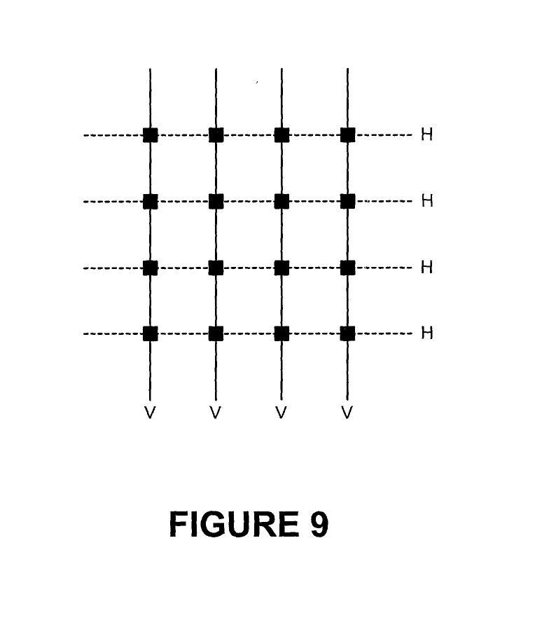

As one example of an alternative embodiment, FIG. 7 shows a phase shift mask Ma having a vertical striped pattern. The striped pattern comprises alternating columns of unetched regions U and etched regions E. The dimensions of the regions U and E can be defined to meet the desired contact hole requirement. For example, the etched regions E may be made narrower than the unetched regions U for certain applications. With the method illustrated in FIG. 10, after the first exposure, vertical interference lines V are formed on the photoresist layer corresponding to the transition areas between the etched regions E and un-etched regions U. In the second exposure, the phase shift mask Ma is rotated 90 degree so that the etched regions E and un-etched regions U form horizontal stripes, as shown in FIG. 8. After the second exposure, a set of horizontal interference lines H on the photoresist layer (where the photoresist is not exposed to radiation) is formed. As seen in FIG. 9, the vertical lines V defined from the first exposure intersect with the horizontal lines H defined from the second exposure. The intersection points C are formed for the contact holes where the photoresist layer was not exposed to radiation during either the first or second exposure. The photoresist in the areas of C that was not exposed is then developed and removed away in the development process. The resulting contact holes after etch and resist strip and clean is a two dimensional array of contact holes C that is usable for memory arrays and other periodic structures.

The above description of illustrated embodiments of the invention, including what is described in the abstract, is intended to be extendable and unlimited to the precise forms disclosed.

While specific embodiments of, and examples for, the invention are described herein for illustrative purpose, various equivalent modifications are possible within the scope of the invention, as those skilled in the art will recognize. These modifications can be made to the invention in radiation of the detailed description. The terms used in the following claims should not be construed to limit the invention to specific embodiments disclosed in the specification and the claims. Rather, the scope of the invention is to be determined entirely by the following claims, which are to be construed in accordance with established doctrines of claim interpretation.

What is claimed is:

1. A method comprises:
forming a phase shift mask having a periodic pattern of etched regions and unetched regions;
performing a first exposure to a photoresist layer formed on a substrate through the phase shift mask;
laterally offsetting the phase shift mask; and
performing a second exposure to the photoresist layer through the laterally offset phase shift mask.

2. The method of claim 1 wherein said photoresist is a negative photoresist.

3. The method of claim 1 wherein said phase shift mask is formed of quartz.

4. The method of claim 2 further comprises:
developing said negative photoresist layer; and
etching said substrate using said developed photoresist layer as a etch mask.

5. The method of claim 1 wherein said periodic pattern is a checkerboard pattern of etched regions and unetched regions.

6. The method of claim 1 wherein said periodic pattern comprises alternating stripes of etched regions and unetched regions.

7. The method of claim 5 wherein said lateral offsetting comprises shifting said phase shift mask in both an x direction and a y direction.

8. The method of claim 7 wherein said offsetting has a magnitude less than a dimension of said etched region.

9. The method of claim 6 wherein said lateral offsetting comprises rotating said phase shift mask.

10. The method of claim 10 wherein said rotating is a ninety-degree rotation.

11. The method of claim 1 wherein said lateral offsetting comprises rotating and shifting said phase shift mask.

12. The method of claim 1 wherein said etched regions have a portion of the phase shift mask removed to a depth sufficient to cause exposing radiation passing through to be 180 degrees out of phase with radiation passing through said unetched regions.

13. A semiconductor product having contact holes formed by:
forming a phase shift mask having a repetitive pattern of etched regions and unetched regions;
performing a first exposure to a photoresist layer formed on a substrate through said phase shift mask;
laterally offsetting the position of said phase shift mask relative to said photoresist layer;
performing a second exposure to said photoresist layer through said laterally offset phase shift mask;
developing said photoresist layer; and
etching said contact holes in said substrate using said developed photoresist layer as a mask.

14. The product of claim 13 wherein said photoresist used is a negative photoresist.

15. The product of claim 13 wherein said phase shift mask used is formed from quartz.

16. The product of claim 13 wherein said repetitive pattern of the phase shift mask used is a checkerboard pattern of etched regions and unetched regions.

17. The product of claim 13 wherein said repetitive pattern of the phase shift mask used comprises alternating stripes of etched regions and unetched regions.

18. The product of claim 16 wherein said lateral offsetting comprises shifting said phase shift mask in both an x direction and a y direction.

19. The product of claim 18 wherein said offsetting has a magnitude less than a dimension of said etched region.

20. The product of claim 17 wherein said lateral offsetting comprises rotating said phase shift mask used.

21. The product of claim 20 wherein said rotating is a ninety-degree rotation.

22. The product of claim 13 wherein said etched regions have a portion of the phase shift mask used are removed to a depth sufficient to cause exposing radiation passing therethrough to be 180 degrees out of phase with radiation passing through said unetched regions.

23. A method comprises:
using a phase shift mask to perform a first exposure of a photoresist layer formed atop of a substrate, wherein said phase shift mask includes etched regions and unetched regions;
adjusting the positioning of said phase shift mask relative to said photoresist layer;
performing a second exposure of said photoresist layer;
developing said photoresist layer; and
using said photoresist layer as a mask to etch said substrate.

24. The method of claim 23 wherein said photoresist is a negative photoresist.

25. The method of claim 23 wherein said etched regions and said unetched regions form a repetitive checkerboard pattern.

26. The method of claim 23 wherein said etched regions and said unetched regions form repetitive pattern of alternating stripes.

27. The method of claim 23 wherein said offsetting comprises shifting said phase shift mask in both an x direction and a y direction.

28. The method of claim 27 wherein said offsetting has a magnitude less than a dimension of said etched region.

29. The method of claim 23 wherein said offsetting comprises rotating said phase shift mask.

30. The method of claim 23 wherein said offsetting comprises rotating and shifting said phase shift mask.

31. The method of claim 23 wherein said etched regions have a portion of the phase shift mask removed to a depth sufficient to cause exposing radiation passing therethrough to be 180 degrees out of phase with radiation passing through said unetched regions.
